(19) United States
(12) Patent Application Publication
(10) Pub. No.: US 2024/0363553 A1
(43) Pub. Date: Oct. 31, 2024

(54) SEAL RING STRUCTURE FOR MULTI-GATE DEVICE AND THE METHOD THEREOF

(71) Applicant: Taiwan Semiconductor Manufacturing Company, Ltd., Hsin-Chu (TW)

(72) Inventors: Chun Yu CHEN, Hsinchu (TW); Yen Lian LAI, Hsinchu (TW)

(21) Appl. No.: 18/308,003

(22) Filed: Apr. 27, 2023

(51) Int. Cl. H01L 23/58; H01L 21/8234; H01L 27/088; H01L 29/423; H01L 29/66; H01L 29/786

(52) U.S. Cl. CPC H01L 23/585; H01L 21/823437; H01L 21/823475; H01L 27/088; H01L 29/42392; H01L 29/66545; H01L 29/78696

(57) ABSTRACT

The present disclosure provides a semiconductor structure that includes a substrate having a circuit region and a seal ring region around the circuit region, first active regions of a first width disposed in the circuit region, second active regions of a second width disposed in the seal ring region, first gate structures disposed on the first active regions, and second gate structures disposed on longitudinal edges of the second active regions. The first gate structures are longitudinally oriented to be orthogonal with the first active regions. The second gate structures are longitudinally oriented to be in parallel with the second active regions. The second width is greater than the first width.

### BACKGROUND

In semiconductor technologies, a semiconductor wafer is processed through various fabrication steps to form integrated circuits (IC). Typically, several circuits or IC dies are formed onto the same semiconductor wafer. The wafer is then diced to cut out the circuits formed thereon. To protect the circuits from moisture degradation, ionic contamination, and dicing processes, a seal ring is formed around each circuit die. This seal ring is formed during fabrication of the many layers that comprise the circuits, including both the front-end-of-line (FEOL) processing, the middle-end-of-line (MEOL) structures, and back-end-of-line processing (BEOL). The FEOL and MEOL include forming transistors, capacitors, diodes, and/or resistors onto the semiconductor substrate. The BEOL includes forming metal layer interconnects and vias that provide routing to the components of the FEOL.

Although existing seal ring structures and fabrication methods have been generally adequate for their intended purposes, improvements are needed. For example, the seal ring structure is not robust to provide protection to the circuit devices. For at least these reasons, improvements are needed to the seal ring structure and the method making the same to address those issues.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a top view of a semiconductor structure, according to various aspects of the present disclosure.

FIGS. 2, 3A, 3B, 4A, 4B, 5A, 5B are top views of the areas A, B, and C of the semiconductor structure 100, respectively, according to various aspects of the present disclosure.

FIGS. 6A, 6B, 7A, 7B, 8A, 8B, 9A, and 9B are cross-sectional views of the semiconductor structure in the areas A and B of FIG. 1, according to various aspects of the present disclosure.

FIG. 10 is a flowchart of a method making the semiconductor structure in FIG. 1, according to various aspects of the present disclosure.

FIGS. 11, 12, 13, 14, 15, 16, 17, 18, 19, 20, and 21 illustrate cross-sectional views of the semiconductor structure during a fabrication process with respect to the method of FIG. 10, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below.” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Still further, when a number or a range of numbers is described with “about,” “approximate,” and the like, the term encompasses numbers that are within certain variations (such as +/−10% or other variations) of the number described, in accordance with the knowledge of the skilled in the art in view of the specific technology disclosed herein, unless otherwise specified. For example, the term “about 5 nm” may encompass the dimension range from 4.5 nm to 5.5 nm, 4.0 nm to 5.0 nm, etc.

A semiconductor substrate, such as an integrated circuit chip, includes a circuit region surrounded by a seal ring region. The seal ring region provides protection to the integrated circuit in the circuit region from various environment damages, such as moisture and chemical. The seal ring structure includes multiple layers vertically extending from the substrate, through an interconnect structure, and up to the passivation layer. The seal ring structure may be formed simultaneously with the circuit features in the circuit region (or circuit area, chip area, device region, chip die) through various fabrication stages, such as in the front-end-of-line (FEOL) structures, the middle-end-of-line (MEOL) structures, and/or in back-end-of-line (BEOL) structures. As used herein, FEOL structures include structural features of transistors or other semiconductor devices fabricated on a semiconductor substrate; MEOL structures include source/drain contact vias or gate contact vias; and BEOL structure include interconnect structures and passivation structures over the interconnect structures. In the BEOL processes, conductive lines or vias are formed in multiple metal layers stacked over the semiconductor substrate to connect various features in the circuit region. Simultaneously, conductive rings and via rings are formed in the seal ring region of each metal layer. The components in the seal ring region, such as transistors, conductive rings, and the via rings, do not provide electrical functions for the semiconductor structure as their counterparts in the circuit region do. Instead, the components in the seal ring region enclose and protect the circuit region from moisture, mechanical stress, or other defect-generating mechanism. The differences in functionality cause the seal ring region to have properties different from the circuit region, such as pattern sizes and/or pattern density. The differences in properties may cause processing issues such as dishing in chemical mechanical planarization (CMP) processes, especially in areas between the seal ring region and the circuit region, and/or uneven etching in etching processes.

This application generally relates to a semiconductor structure and fabrication processes thereof, and more particularly to a seal ring region of the semiconductor structure and the fabrication processes thereof. The seal ring region is designed to have proper properties (e.g., proper line widths, line pitches, and/or line pattern densities) that help buffering the differences between the circuit region and the seal ring region, thereby providing smooth transition from the circuit region to the seal region. The smooth transition alleviates process issues such as dishing during subsequent CMP processes and/or uneven etching during subsequent etching processes. Those of ordinary skill in the art should appreciate that they may readily use the present disclosure as a basis for designing or modifying other processes and structures for carrying out the same purposes and/or achieving the same advantages of the embodiments introduced herein.

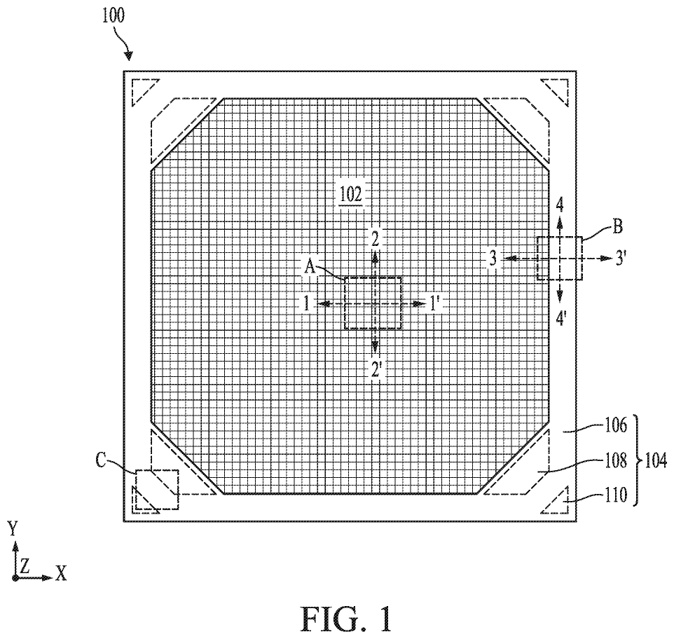

FIG. 1 is a top view of a semiconductor structure 100 according to the present disclosure. The semiconductor structure 100 (such as a manufactured wafer or a part thereof) includes a circuit region 102 that is enclosed by a seal ring region 104. In some embodiments, the semiconductor structure 100 may include other seal ring region(s) enclosing the seal ring region 104 or other seal ring region(s) enclosed by the seal ring region 104. Also, the seal ring region 104 may enclose other circuit region(s). The circuit region 102 may include any circuits, such as memory, processor, transmitter, receiver, and so on. The exact functionality of the circuit region 102 is not limited by the present disclosure.

In the present embodiment, the seal ring region 104 includes seal ring structures 106 that have a rectangular or substantially rectangular periphery fully surrounds the circuit region 102. The four corners of the rectangular periphery are replaced by sloped corner lines that connect the adjacent edges of the rectangular. In the present embodiments, each of the sloped corner lines is substantially 45° to the X direction. The seal ring region 104 further includes four inner corner regions 108 disposed along the corresponding sloped corner lines and between the seal ring structure 106 and the circuit region 102. The seal ring region 104 further includes four outer corner regions 110 disposed at corners of the seal ring region 104. Each of the outer corner regions 110 is disposed outside the seal ring structure 106 and along corresponding sloped corner lines. The inner corner regions 108 and the outer corner regions 110 provide further mechanical strength for the seal ring region 104. The outer corner region 110 is substantially triangular in shape and the inner corner region 108 is substantially trapezoidal in shape. In some embodiments, the seal ring structures 106 may provide openings in selected locations and/or selected layers to allow interconnects between the circuit region 102 and other circuit regions not shown in FIG. 1. In some embodiments, the seal ring region 104 may have a non-rectangular shape.

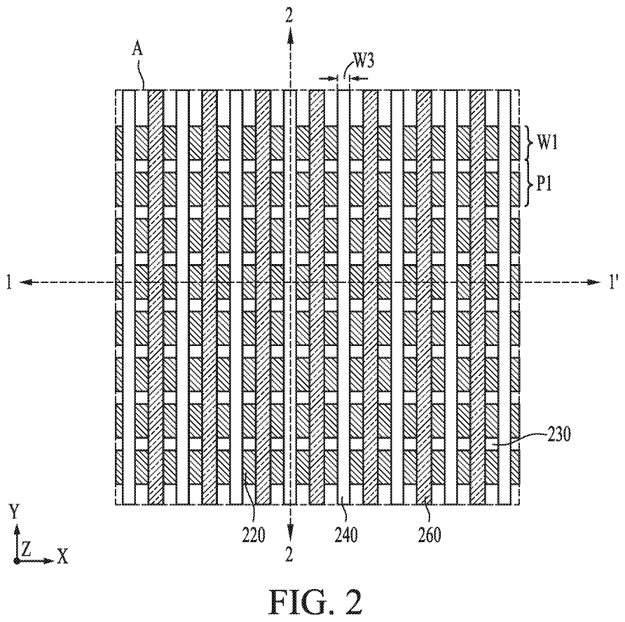

FIG. 2 is a zoomed-in top view of the area A in the circuit region 102 shown in FIG.1. The circuit region 102 includes active regions 220 oriented lengthwise along the X direction, isolation structures 230 disposed between and separating the active regions 220, gate structures 240 oriented lengthwise along the Y direction and across over the active regions 220, and contact structures 260 oriented lengthwise along the Y direction and across over the active regions 220. The above elements form a matrix, and transistors are formed in the intersections between the active regions 220 and the gate structures 240. The transistors may be planar metal-oxide-semiconductor field effect transistor (MOSFET) or multi-gate transistors. A multi-gate device generally refers to a device having a gate structure, or portion thereof, disposed over more than one side of a channel region. Fin-like field effect transistors (FinFETs) and multi-bridge-channel (MBC) transistors are examples of multi-gate devices that have become popular. A FinFET has an elevated channel wrapped by a gate on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor. An active region may be an “oxide-definition (OD) region” where a source, a drain, and a channel under a gate of the transistor are formed. In a multi-gate device, the active region 220 may be a continuous active region protruding from the substrate like a “fin” or a group of channel layers (channel members) vertically stacked in forming a fin-like shape and suspended above the substrate, such that the top surface of the active region 220 is above the top surface of the isolation structures 230. The active regions 220 in a multi-gate device are also referred to as fin-like active regions. The isolation structures 230 are surrounding each of the active regions 220 so that various active regions 220 are separated and isolated from each other.

It is noted that while the active regions 220 and gate structures 240 are depicted in FIG. 2 as extending continuously along the X direction or the Y direction, they may be divided into segments by dielectric features according to the circuit design of the semiconductor structure 100.

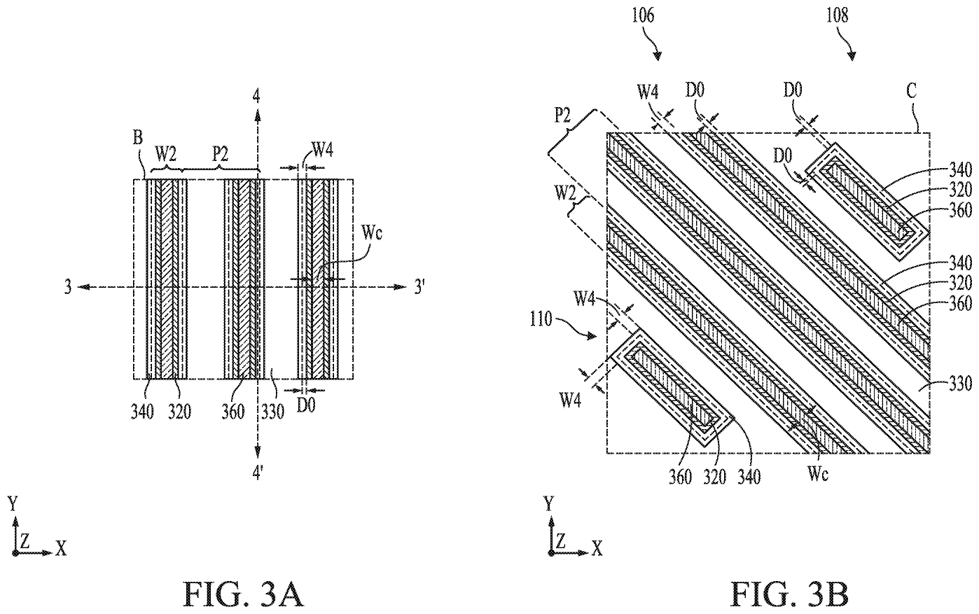

FIG. 3A is a zoomed-in top view of the area B in the seal ring region 104 shown in FIG. 1. The seal ring region 104 includes active regions (e.g., fin-like active regions) 320 disposed lengthwise along the Y direction, isolation structures 330 disposed between and separating the active regions 320, gate structures 340 disposed lengthwise along the Y direction, and contact structures 360 disposed over the active regions 320 and lengthwise along the Y direction. Referring back to FIG. 1, each of the active regions 320, the gate structures 340, the contact structures 360, and the isolation structures 330 forms a continuous ring shape completely surrounding the circuit region 102, and thereby may be referred to as active region rings 320, gate rings 340, contact rings 360, and isolation rings 330 hereafter. Each of the active region rings 320, the gate rings 340, the contact rings 360, and the isolation rings 330 encloses (or completely surrounds) the circuit region 102 substantially concentrically and extends substantially parallel to each other.

FIG. 3B is a zoomed-in top view of the area C in the seal ring region 104 shown in FIG. 1. The active regions 320, the isolation structures 330, the gate structures 340, and the contact structures 360 in the corners are longitudinally oriented in titled angles (e.g., 45° from the X direction) such that those elements in the seal ring structures 106 are connected to adjacent elements to form continuous rings. Also shown in FIG. 3B, other active regions 320 for filling the outer corner regions 110 and the inner corner regions 108 are segmented.

The seal ring region 104 may include components of FinFET transistors, components of GAA transistors, other types of transistors, and combinations thereof. The components of transistors in the seal ring region 104 are formed simultaneously with the transistors in the circuit region 102 and are consistent with the circuit region 102 in types. For example, the seal ring region 104 includes components similar and corresponding to those in FinFET transistors if the circuit region 102 includes FinFET transistors. In another example, the seal ring region 104 includes components similar and corresponding to those in GAA transistors if the circuit region 102 includes GAA transistors.

Referring to FIGS. 2. 3A, and 3B collectively, the active regions 220 in the circuit region 102 have a first width W₁ and the active regions 320 in the seal ring region 104 have a second width W₂ different from the first width W₁. Particularly, W₂ is substantially greater than W₁. In some embodiments, W₁ ranges between 0.02 μm and 0.08 μm; and W₂ ranges between 0.04 μm and 0.16 μm. A ratio W₂/W₁ ranges from about 1.1 to about 5. This range is not trivial. If the ratio W₂/W₁ is larger than about 5, the active region width differs significantly in the circuit region 102 and the seal ring region 104 such that the non-uniformity may cause dishing effect in subsequent planarization processes (e.g., CMP process), especially in a region between the seal ring region 104 and the circuit region 102. If the ratio W₂/W₁ is smaller than about 1.1, the active regions 320 in the seal ring region 104 is not wide enough to support conductive rings and via rings formed thereon with sufficient widths in the subsequent BEOL processes such that the protection function of the seal ring structures against environment damages, such as moisture and chemical, is compromised.

The active regions 220 in the circuit region 102 have a first pitch P₁ and the active regions 320 in the seal ring region 104 have a second pitch P₂ different from the first pitch P₁. Particularly. P₂ is substantially greater than P₁. In some embodiments, P₁ ranges between 0.05 μm and 0.2 μm; and P₂ ranges between 0.1 μm and 0.4 μm. A ratio P₂/P₁ ranges from about 1.1 to about 5. This range is not trivial. If the ratio P₂/P₁ is larger than about 5, the active region density differs significantly in the circuit region 102 and the seal ring region 104 such that the non-uniformity may cause dishing effect in subsequent planarization processes (e.g., CMP process), especially in a region between the seal ring region 104 and the circuit region 102. If the ratio P₂/P₁ is smaller than about 1.1, the adjacent active regions in the seal ring region 104 is too close to each other such that conductive rings and via rings formed thereon in the subsequent BEOL processes are not sufficiently wide and the protection function of the seal ring structures against environment damages, such as moisture and chemical, is compromised.

The first width W₁ and the first pitch P₁ collectively define a first active region aerial density in the circuit region 102, and the second width W₂ and the second pitch P₂ collectively define a second active region aerial density in the seal ring region 104. Taking FIG. 3A as an example, the active region aerial density is calculated as the area occupied by the segments of the active regions 320 within the area B (the dashed box) divided by the total area of the area B. In some embodiments, each of the first and second active region aerial density ranges from about 20% to about 60%. Particularly, a difference between the first and second active region aerial densities is within 10%. For example, if the first active region aerial density is about 40% (of the area A), the second active region aerial density is in a range from about 30% to about 50% (of the area B). Keeping the difference between the first and second active region aerial densities within 10% is not arbitrary. If the difference is beyond 10%, the active region density differs significantly in the circuit region 102 and the seal ring region 104 such that the non-uniformity may cause dishing effect in subsequent planarization processes (e.g., CMP process), especially in a region between the seal ring region 104 and the circuit region 102, and over etching may occur in the region with the less density in subsequent etching processes.

The active regions 320 in the seal ring region 104 are further different from the active regions 220 in the circuit region 102 in term of continuity. The active regions 220 in the circuit region 102 are not continuous and are segmented, depending on individual circuit and design layout. However, the active regions 320 in the seal ring region 104 are continuously extending around the circuit region 102. FIG. 3A illustrates three (3) active regions 320 in the seal ring region 104, each is continuously extending into a ring shape. FIG. 3B further illustrates one (1) active region 320 that is segmented in the inner corner region 108 and one (1) active region 320 that is segmented in the outer corner region 110. It is noted that a number of continuous and segmented active regions 320 in the seal ring region 104 is not limited to the number illustrated in FIGS. 3A and 3B, and may include any proper number, depending on individual circuit and design.

The contact structures 260 in the circuit region 102 are longitudinally oriented in the Y direction, which is generally perpendicular to the orientation (X direction) of the active regions 220 in the circuit region 102. In contrary, the contact structures 360 in the seal ring region 104 are longitudinally oriented in the Y direction, which is in parallel with the orientation (Y direction) of the active regions 320 in the seal ring region 104. Furthermore, the contact structures 360 are completely landing on the respective active regions 320. For example, the contact structures 360 are landing on the center of the active regions 320 with margins on both sides, such as equal margin on both sides. In this case, the width We of the contact structures 360 is less than the width W₂ of the active regions 320. In some embodiments, the ratio W₂/W_{c} ranges between about 1.5 and about 2. Such configuration of the contact structures 360 and active regions 320 in the seal ring region 104 make the seal ring structure more robust. The continuity from the active regions 320 to the contact structures 360 provides better scaling effect. In some embodiments, the contact structures 360 in the seal ring region 104 have a width that is larger than that of the contact structures 260 in the circuit region 102 due to the relatively wider active regions 320 in the seal ring region 104.

The gate structures 240 in the circuit region 102 are longitudinally oriented in the Y direction, which is generally perpendicular to the orientation (X direction) of the active regions 220 in the circuit region 102. In contrary, the gate structures 340 in the seal ring region 104 are longitudinally oriented in the Y direction, which is in parallel with the orientation (Y direction) of the active regions 320 in the seal ring region 104. Furthermore, the gate structures 340 are landing on (or covering) edges (illustrated as dotted lines in FIGS. 3A and 3B) of the respective active regions 320. For an active region ring 320, a first gate ring 340 is landing on an inner edge of the active region ring 320 and partially overlaps with an inner portion of the top surface of the active region ring 320 in a top view, and a second gate ring 340 is landing on an outer edge of the active region ring 320 and partially overlaps with an outer portion of the top surface of the active region ring 320. The second gate ring 340 encloses (or completely surrounds) the first gate ring 340. Each of the first and second gate rings 340 overlaps a width D₀ of about 5 nm to about 15 nm of the respective edge portion of the active region ring 320. For a segmented active region 320 in either the inner corner region 108 or the outer corner region 110, a gate ring 340 is landing on all four edges of the segmented active region 320 and partially overlaps with edge portions of the segmented active region 320, such that in a top view the gate ring 340 encloses (or completely surrounds) the segmented active region 320. The gate ring 340 overlaps a width D₀ of about 5 nm to about 15 nm of each edge portion of the respective segmented active region ring 320.

In the present embodiments, the gate structures 240 in the circuit region 102 and the gate structures 340 in the seal ring region 104 are simultaneously formed with same compositions, such as by gate replacement. For example, the gate structures 240 and 340 include a gate dielectric layer (such as an interfacial layer and a high-k dielectric material layer) and a gate electrode (such as metal materials that further include a work function metal layer and a fill metal layer). For GAA transistors, the active region includes multiple vertically stacked channel layers each wrapped around by the gate structure. In the circuit region during the gate replacement process, sacrificial layers stacked between adjacent channel layers are removed, sparing space for the gate structure to fill in. Since in the seal ring region 104 the gate structures 340 extend lengthwise in the same direction as the active regions 320, depositing the gate structures 340 on edges of the active regions 320 such that the gate structures 340 only partially overlap with the active regions 320 allows the sacrificial layers to be removed in the seal ring region 104 as well as in the circuit region 102. Such configuration allows the uniformity of material compositions in the active regions in both the circuit region 102 and the seal ring region 104. The material composition uniformity effectively mitigates over etching and dishing effect in subsequent planarization processes (e.g., CMP process), especially in a region between the seal ring region 104 and the circuit region 102. Such configuration also allows relatively larger source/drain region width and consequently relatively wider contact structures 360 in the seal ring region 104, which provides a more robust seal ring structure to resist external stress and mist.

The gate structures 240 in the circuit region 102 have a width W₃ and the gate structures 340 in the seal ring region 104 have a width W₄ substantially the same with the width W₃ (W₃=W₄). The first gate structure aerial density in the circuit region 102 and the second gate structure aerial density in the seal ring region 104 are generally similar. Taking FIG. 3A as an example, the gate structure aerial density is calculated as the area occupied by the segments of the gate structures 340 within the area B (the dashed box) divided by the total area of the area B. In some embodiments, each of the first and second gate structure acrial density ranges from about 10% to about 50%. Particularly, a difference between the first and second gate structure aerial densities is within 10%. For example, if the first active region aerial density is about 30% (of the area A), the second active region aerial density is in a range from about 20% to about 40% (of the area B). Keeping the difference between the first and second gate structure acrial densities within 10% is not arbitrary. If the difference is beyond 10%, the gate structure density differs significantly in the circuit region 102 and the seal ring region 104, such that the non-uniformity may cause dishing effect in subsequent planarization processes (e.g., CMP process), especially in a region between the seal ring region 104 and the circuit region 102, and over etching may occur in the region with the less density in subsequent etching processes. Keeping the widths of the gate structures substantially the same also ensures the uniformity of the elements between the circuit region 102 and the seal ring region 104.

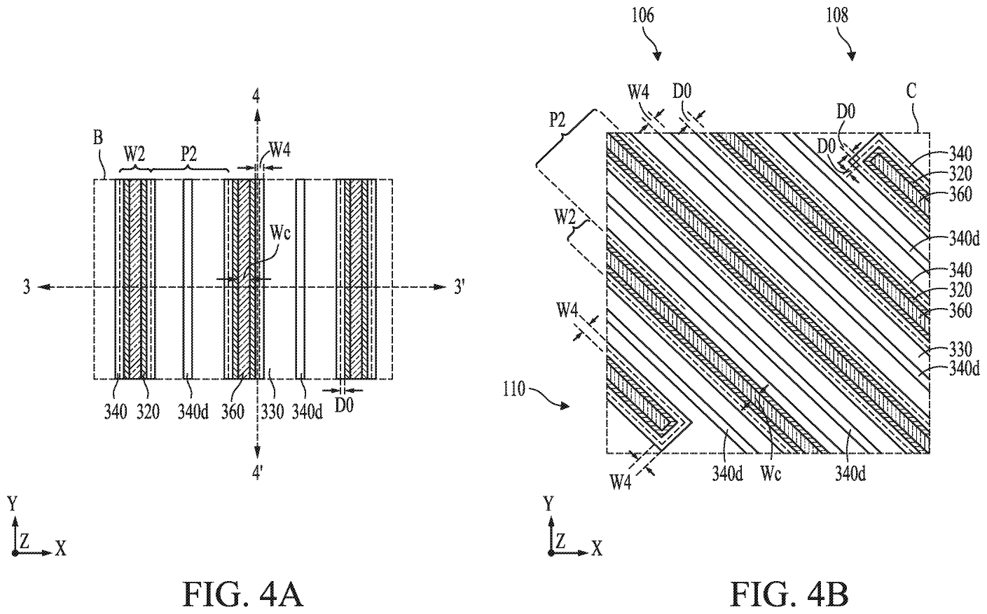

In some embodiments, particularly when the second pitch P2 of the active regions 320 is larger than first pitch P1 of the active regions 220 to some extent, the gate structures 340 become sparse in the seal ring region 104, such that the difference between the gate structure aerial densities in the circuit region 102 and the seal ring region 104 is beyond 10%. In such a scenario, dummy gate structures 340d may be inserted between the gate structures 340 to increase the gate structure aerial density. FIGS. 4A and 4B illustrate such an implementation. In FIG. 4A, a dummy gate structure 340d is inserted between two adjacent active region rings 320. The dummy gate structure 340d also forms a ring. In FIG. 4B. a dummy gate structure 340d is inserted between the active region ring 320 and the segmented active region 320 in the corner regions. The dummy gate structure 340d may be a ring or a segment. Although not shown in FIG. 4B, within each of the inner corner region 108 and the outer corner region 110, a segmented dummy gate structure 340d may be inserted between two adjacent segmented active regions 320. The dummy gate structures 340d are deposited on the isolation structures 330 and distant from edges of the nearby active regions 320. FIGS. 4A and 4B illustrate one (1) dummy gate structure 340d inserted between two adjacent active regions 320. It is noted that a number of dummy gate structures 340d inserted is not limited to the number illustrated in FIGS. 4A and 4B, and may include any proper number, depending on the tuning of the gate structure density. For example, there may be two (2) or three (3) dummy gate structures 340d between two adjacent gate structures 340. In some embodiments, the dummy gate structures 340d and the gate structures 340 have the same width. Since the dummy gate structures 340d and the gate structures 340 are simultaneously formed with same compositions, the dummy gate structures 340d and the gate structures 340 may both be denoted as gate structures 340.

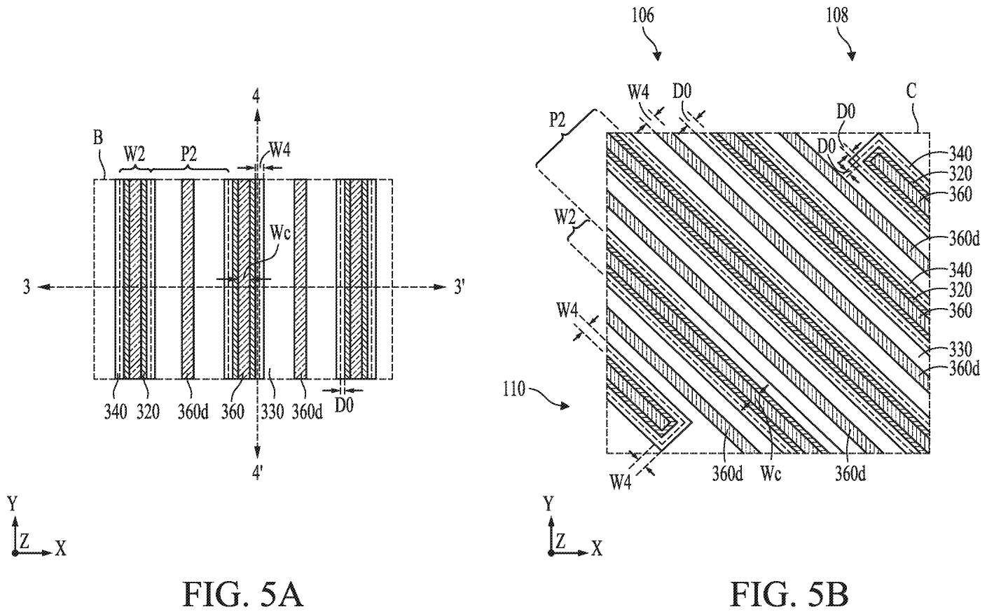

In some alternative embodiments, dummy contact structures 360d may be inserted between the contact structures 360 to increase the contact structure acrial density. FIGS. 5A and 5B illustrate such an implementation. In FIG. 5A, a dummy contact structure 360d is inserted between two adjacent active region rings 320. The dummy contact structure 360d also forms a ring. In FIG. 4B, a dummy contact structure 360d is inserted between the active region ring 320 and the segmented active region 320 in the corner regions. The dummy contact structure 360d may be a ring or a segment. Although not shown in FIG. 5B, within each of the inner corner region 108 and the outer corner region 110, a segmented dummy contact structure 360d may be inserted between two adjacent segmented active regions 320. The dummy contact structures 360d are deposited above the isolation structures 330 and distant from edges of the nearby active regions 320. FIGS. 5A and 5B illustrate one (1) dummy contact structure 360d inserted between two adjacent active regions 320. It is noted that a number of dummy contact structures 360d inserted is not limited to the number illustrated in FIGS. 5A and 5B, and may include any proper number, depending on the tuning of the gate structure density. For example, there may be two (2) or three (3) dummy contact structures 360d between two adjacent contact structures 360. In some embodiments, the dummy contact structures 360d and the contact structures 360 have the same width. Since the dummy contact structures 360d and the contact structures 360 are simultaneously formed with same compositions, the dummy contact structures 360d and the contact structures 360 may both be denoted as contact structures 360.

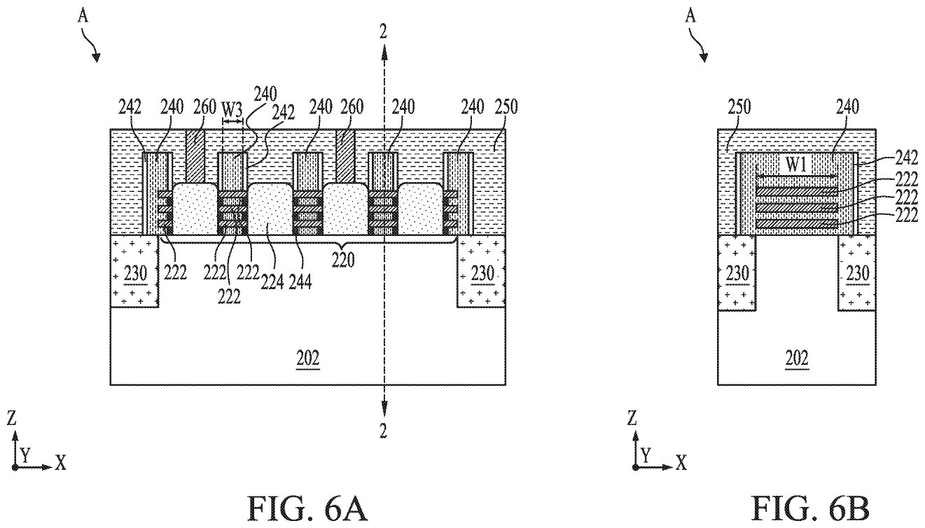

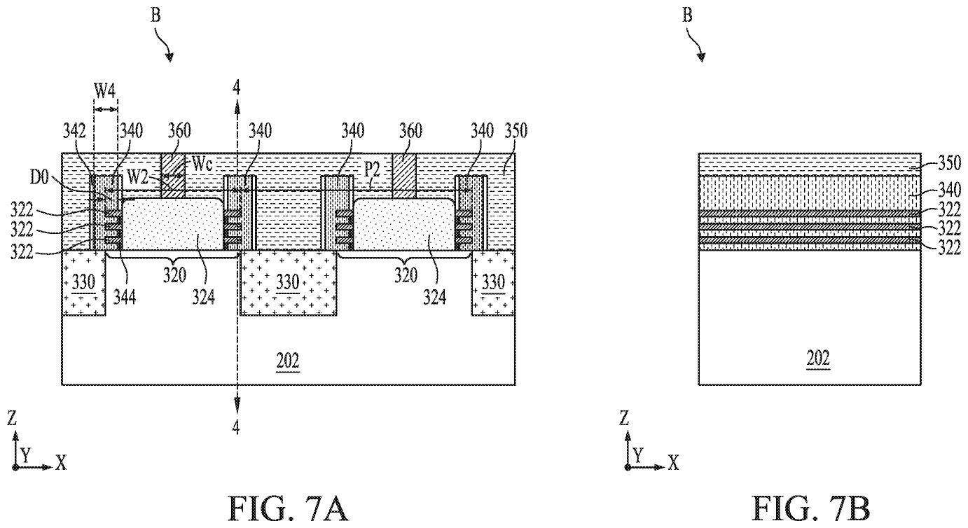

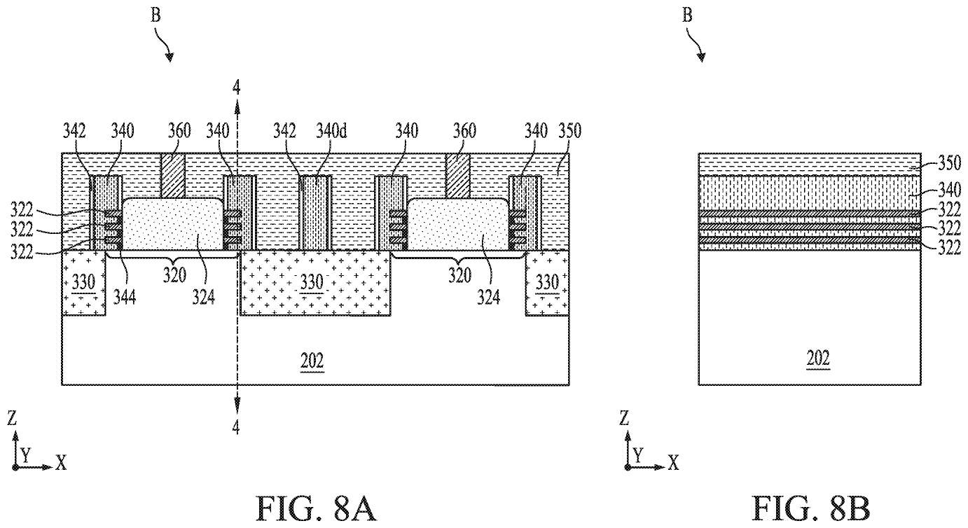

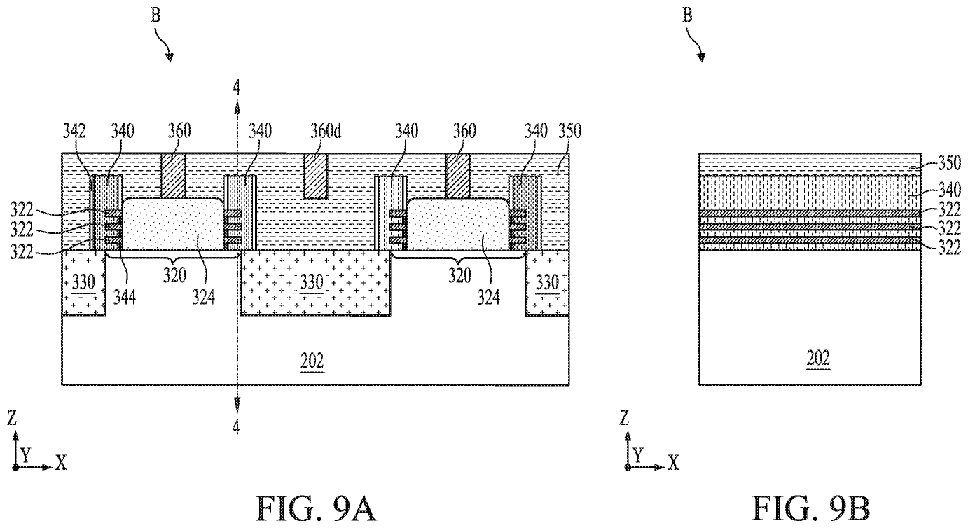

FIG. 6A is a sectional view of the semiconductor structure 100 in the area A of FIG. 1 cut along 1-1′ of FIG. 1 or FIG. 2; FIG. 6B is a sectional view of the semiconductor structure 100 in the area A of FIG. 1 cut along 2-2′ of FIG. 1 or FIG. 2; FIG. 7A is a sectional view of the semiconductor structure 100 in the area B of FIG. 1 cut along 3-3′ of FIG. 1 or FIG. 3A; FIG. 7B is a sectional view of the semiconductor structure 100 in the area B of FIG. 1 cut along 4-4′ of FIG. 1 or FIG. 3A; FIG. 8A is an alternative sectional view of the semiconductor structure 100 in the area B of FIG. 1 cut along 3-3′ of FIG. 1 or FIG. 4A; FIG. 8B is a sectional view of the semiconductor structure 100 in the area B of FIG. 1 cut along 4-4′ of FIG. 1 or FIG. 4A; FIG. 9A is an alternative sectional view of the semiconductor structure 100 in the area B of FIG. 1 cut along 3-3′ of FIG. 1 or FIG. 5A; FIG. 9B is a sectional view of the semiconductor structure 100 in the area B of FIG. 1 cut along 4-4′ of FIG. 1 or FIG. 5A, constructed in accordance with some embodiments. Note that only substrate, active regions, isolation structures, gate structures, inner spacers, gate spacers, interlayer dielectric (ILD) layer, and contact structures are illustrated in those figures. Other features, such as interconnect structures, are to be described later.

In FIGS. 6A and 6B, the circuit region 102 includes multi-gate devices, such as functional GAA transistors, formed on the substrate 202. A GAA transistor includes multiple channel layers (or referred to as channel members) 222 vertically stacked on a top portion of the substrate 202. The channel layers 222 may include silicon (Si). The top portion of the substrate 202 protrudes from the rest portion of the substrate 202 and is surrounded by the isolation structures 230. The isolation structures 230 may be shallow trench isolation (STI) structures. A gate structure 240 extends to wrap around of and couple with each of the vertically stacked multiple channel layers 222. The gate structure 240 includes a gate dielectric layer (that further includes a high-k dielectric material) and a gate electrode (that further includes metal). Gate spacers 242 are disposed on sidewalls of the gate structure 240. The gate spacers 242 include one or more dielectric materials, such as silicon oxide, silicon nitride, silicon oxynitride or a combination thereof.

The source/drain (S/D) epitaxial features (or source/drain feature) 224 are disposed on opposite sides of the gate structure 240 and connect each of the vertically stacked multiple channel layers 222. As used herein, a source/drain feature, or “S/D feature,” may refer to a source or a drain of a device. It may also refer to a region that provides a source and/or drain for multiple devices. The source/drain features 224 are isolated from the gate structure 240 by the gate spacers 242 and inner spacers 244. The inner spacers 244 include one or more dielectric material, such as silicon oxide, silicon nitride, silicon oxynitride or a combination thereof. An interlayer dielectric (ILD) layer 250 is disposed on sidewalls and top surfaces of the gate structures 240, the gate spacers 242, the source/drain features 224, and the isolation structures 230. The ILD layer 250 may include or be made of materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 250 may be a multi-layer structure, such as including a lower ILD layer and an upper ILD layer.

The contact structures 260 are disposed on the top surface of the source/drain features 224 and extends through the ILD layer 250. The contact structures 260 may also be referred to as the source/drain contacts. In some embodiments, a silicide feature (not shown) is formed between the source/drain features 224 and the contact structures 260 to reduce contact resistance. The contact structures 260 may include any suitable conductive material, such as Co, W, Ru, Cu, Al, Ti, Ni, Au, Pt, Pd, TiN, TaN, Ta, and/or other suitable conductive materials.

In FIGS. 7A and 7B, the seal ring region 104 includes multi-gate devices, such as non-functional GAA transistors, formed on the substrate 202. Similar to a functional GAA transistor, a non-functional GAA transistor includes multiple channel layers (or referred to as channel members) 322 vertically stacked on a top portion of the substrate 202. The channel members 322 may include silicon (Si). The top portion of the substrate 202 protrudes from the rest portion of the substrate 202 and is surrounded by the isolation structures 330. The isolation structures 330 may be shallow trench isolation (STI) structures. A gate structure 340 is deposited on edge portions of the vertically stacked multiple channel members 322 and extends to fill the gaps between adjacent ones of the vertically stacked multiple channel members 322. For each channel member 322, the gate structure 340 covers the top surface, sidewall surface, and bottom surface of an outer edge portion of the respective channel member 322. The gate structure 340 includes a gate dielectric layer (that further includes a high-k dielectric material) and a gate electrode (that further includes metal). Gate spacers 342 are disposed on sidewalls of the gate structure 340. The gate spacers 342 include one or more dielectric materials, such as silicon oxide, silicon nitride, silicon oxynitride or a combination thereof.

The source/drain epitaxial features (or source/drain feature) 324 are disposed on opposite side of the vertically stacked multiple channel members 322 and connect another edge portions of the vertically stacked multiple channel members 322. That is, each of the channel members 322 has one end partially wrapped around by the gate structure 340 and another end in physical contact with the source/drain feature 324. The source/drain features 324 are isolated from the gate structure 340 by the gate spacers 342 and inner spacers 344. The inner spacers 344 include one or more dielectric material, such as silicon oxide, silicon nitride, silicon oxynitride or a combination thereof. An interlayer dielectric (ILD) layer 350 is disposed on sidewalls and top surfaces of the gate structures 340, the gate spacers 332, the source/drain features 324, and the isolation structures 330. The ILD layer 350 may include or be made of materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 350 may be a multi-layer structure, such as including a lower ILD layer and an upper ILD layer.

The contact structures 360 are disposed on the top surface of the source/drain features 324 and extends through the ILD layer 350. The contact structures 360 may also be referred to as the source/drain contacts. In some embodiments, a silicide feature (not shown) is formed between the source/drain features 324 and the contact structures 360 to reduce contact resistance. Alternatively, in some embodiments, the silicide feature between the source/drain features and the source/drain contacts only exists in the circuit region 102 but not in the seal ring region 104, as the silicide feature reduces the contact resistance for functional circuits but not as critical for non-functional elements and may be skipped from formation. For example, during the silicide formation process on the source/drain features, the source/drain features in the seal ring region 104 may be covered by a resist layer and thus skipped from the silicide formation. The contact structures 360 may include any suitable conductive material, such as Co, W, Ru, Cu, Al, Ti, Ni, Au, Pt, Pd, TiN, TaN, Ta, and/or other suitable conductive materials.

Referring to the alternative embodiment in FIGS. 8A and 8B, the seal ring structure in FIGS. 8A and 8B is similar to the one in FIGS. 7A and 7B. One difference is the dummy gate structure 340d disposed between two adjacent active regions 320. The dummy gate structure 340d improves the overall gate structure uniformity. The dummy gate structure 340d directly lands on a top surface of the isolation structure 330. The dummy gate structures 340d and the gate structures 340 may be simultaneously formed with same compositions. Top surfaces of the dummy gate structures 340d and the gate structures 340 may be coplanar.

Referring to the alternative embodiment in FIGS. 9A and 9B, the seal ring structure in FIGS. 9A and 9B is similar to the one in FIGS. 7A and 7B. One difference is the dummy contact structure 360d disposed between two adjacent active regions 320. The dummy contact structure 360d improves the overall contact structure uniformity. The dummy contact structure 360d is suspended directly above the isolation structure 330 with a distance from the top surface of the isolation structure 330. The dummy contact structures 360d and the contact structures 360 may be simultaneously formed by etching the ILD layer 350 to form contact holes and filling the contact holds with same compositions. While the contact holes for the contact structures 360 ends on the top surface of the source/drain feature 324, the contact holes for the dummy contact structures 360d may further extend into the ILD layer 350. Accordingly, the top surfaces of the dummy contact structures 360d and the contact structures 360 may be coplanar, and the bottom surface of the dummy contact structures 360d may be below the bottom surface of the contact structures 360 and below the top surface of the source/drain features 324. In furtherance of the embodiments, the bottom surface of the dummy contact structures 360d may be below a bottom surface of the topmost channel member 322.

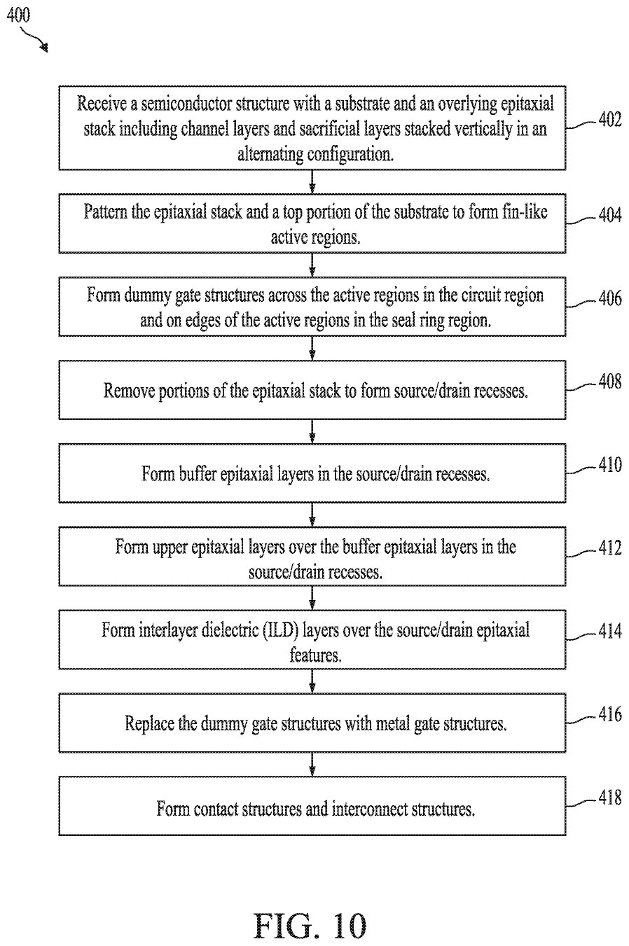

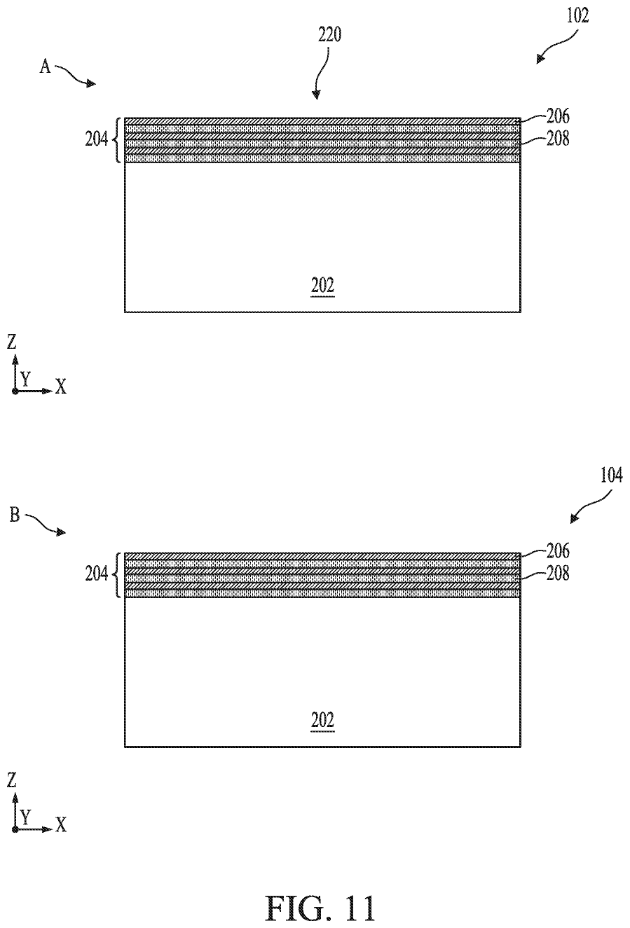

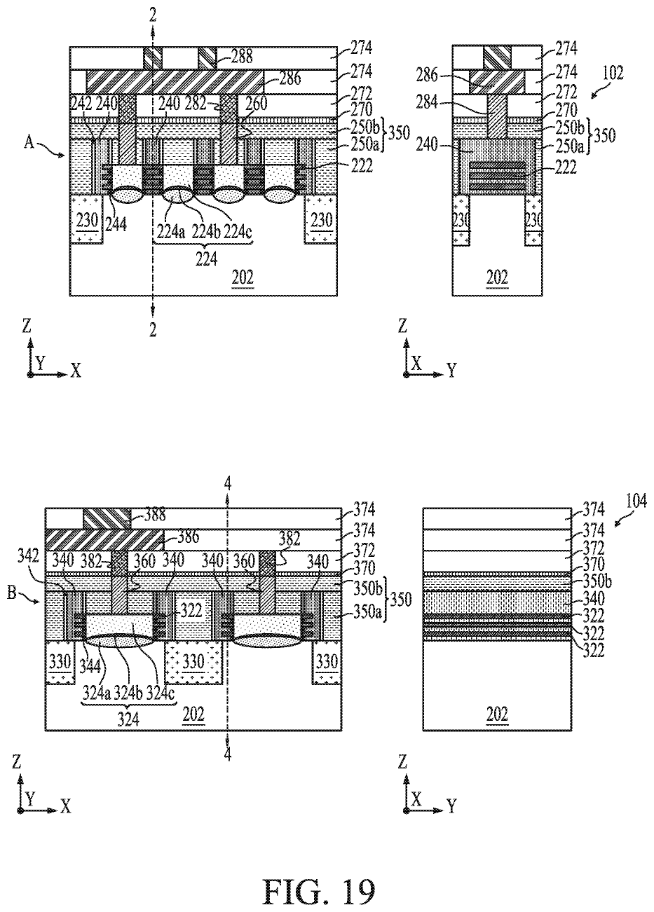

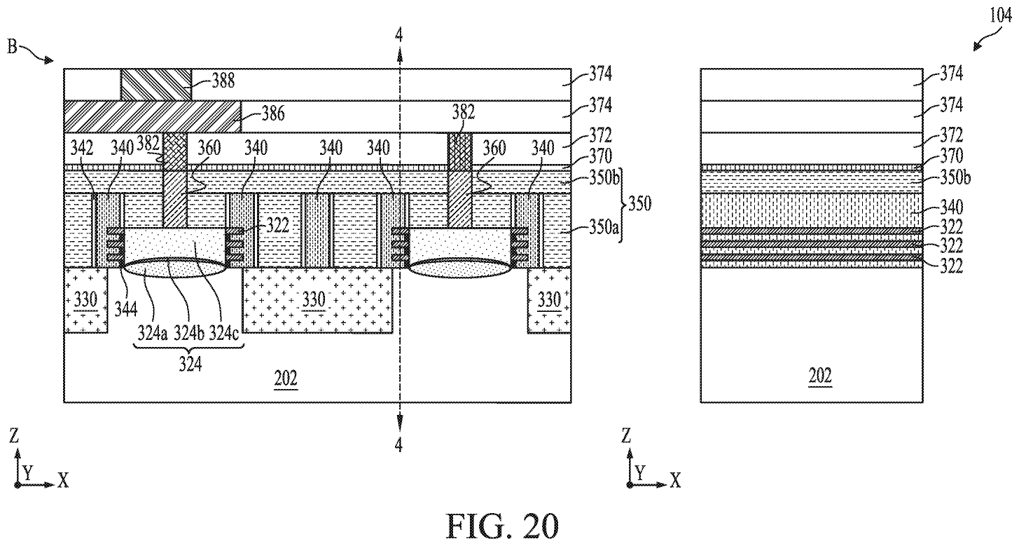

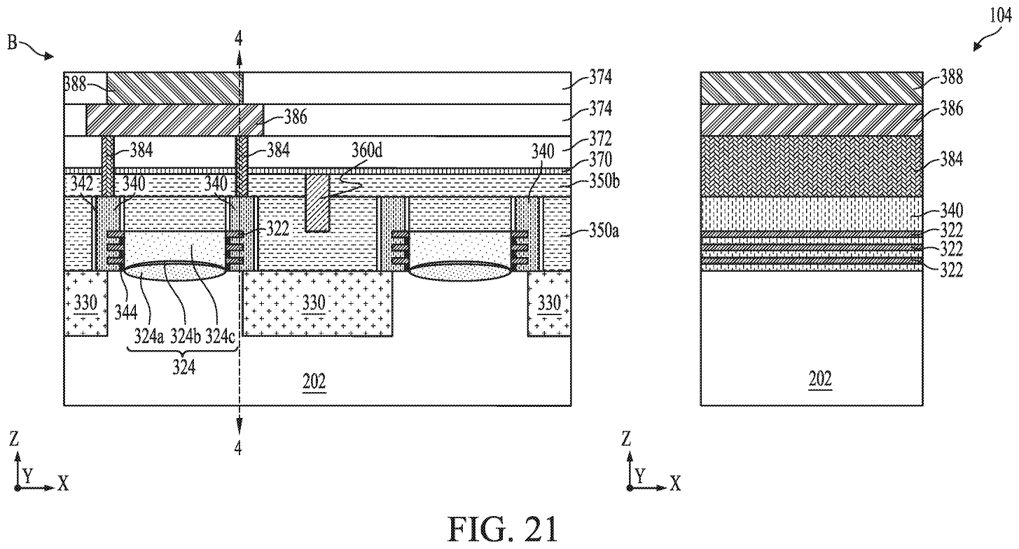

FIG. 10 is a flow chart of a method 400 for fabricating the semiconductor structure 100 discussed above in accordance with FIGS. 1-9B according to various aspects of the present disclosure. Additional operations can be provided before, during, and after method 400, and some of the operations described can be moved, replaced, or eliminated for additional embodiments of method 400. Method 400 is described below in conjunction with FIGS. 11-21, which illustrate various cross-sectional views of the semiconductor structure 100 at various steps of fabrication according to the method 400, in accordance with some embodiments. Among these figures, FIGS. 11-18 illustrate cross-sectional views of the semiconductor structure 100 along lines 1-1′ and 3-3′ in FIG. 1; FIG. 19 illustrates cross-sectional views of the semiconductor structure 100 along lines 1-1′, 2-2′, 3-3′, and 4-4′ in FIG. 1; and FIGS. 20 and 21 illustrate cross-sectional views of alternative embodiments of the semiconductor structure 100 along lines 3-3′ and 4-4′ in FIG. 1.

The semiconductor structure 100 discussed in detail below illustrates components of functional GAA transistors in the circuit region 102 and components of non-functional GAA transistors in the seal ring region 104 as illustrated in conjunction with FIGS. 11-21. The embodiments are provided for simplification and ease of understanding and does not necessarily limit the embodiments to any types of devices, any number of devices, any number of regions, or any configuration of structures of regions. For example, the same inventive concept can be applied in fabricating devices with FinFET transistors. Furthermore, the semiconductor structure 100 may be an intermediate device fabricated during processing of an IC, or a portion thereof, that may comprise static random access memory (SRAM) and/or logic circuits, passive components such as resistors, capacitors, and inductors, and active components such as PFETs, NFETs, FinFETs, GAA FET, MOSFET, CMOS transistors, bipolar transistors, high voltage transistors, high frequency transistors, other memory cells, and combinations thereof. Throughout the present disclosure, unless otherwise excepted, like reference numerals denote like features.

At operation 402, referring to FIGS. 10 and 11, the method 400 is provided with (or receives) a semiconductor structure 100 having a semiconductor substrate (or substrate) 202 and an epitaxial stack 204 above the substrate 202. The substrate 202 is a silicon substrate in the present embodiment. Alternatively, the substrate 202 may comprise another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP. AlInAs, AlGaAs, GaInAs, GaInP, and/or GaInAsP; or combinations thereof. In yet another alternative, the substrate 202 is a semiconductor-on-insulator (SOI) such as a buried dielectric layer.

The epitaxial stack 204 extends continuously from the circuit region 102 to the seal ring region 104. The epitaxial stack 204 includes epitaxial layers 206 of a first composition interposed by epitaxial layers 208 of a second composition. The first and second compositions can be different. The epitaxial layers 206 may include the same composition as the substrate 202. In the illustrated embodiment, the epitaxial layers 208 are silicon germanium (SiGe) and the epitaxial layers 206 are silicon (Si). However, other embodiments are possible including those that provide for a first composition and a second composition having different oxidation rates and/or etch selectivity. For example, in some embodiments, either of the epitaxial layers 206, 208 of the first composition or the second composition may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. In some embodiments, the epitaxial layers 206 and 208 are substantially dopant-free, where for example, no intentional doping is performed during the epitaxial growth process. By way of example, epitaxial growth of the epitaxial layers 206 and 208 of the respective first and second compositions may be performed by a molecular beam epitaxy (MBE) process, a metalorganic chemical vapor deposition (MOCVD) process, and/or other suitable epitaxial growth processes. In various embodiments, the substrate 202 is a crystalline substrate, and the epitaxial layers 206 and 208 are crystalline semiconductor layers.

In some embodiments, each epitaxial layer 206 has a thickness ranging from about 4 nanometers (nm) to about 8 nm. The epitaxial layers 206 may be substantially uniform in thickness. In some embodiments, each epitaxial layer 208 has a thickness ranging from about 4 nm to about 8 nm. In some embodiments, the epitaxial layers 208 of the stack are substantially uniform in thickness. As described in more detail below. the epitaxial layers 206 or portions thereof may form channel member(s) of the to-be-formed multi-gate devices and the thickness is chosen based on device performance considerations. The term channel member(s) (or channel layer(s)) is used herein to designate any material portion for channel(s) in a transistor with nanoscale, or even microscale dimensions, and having an elongate shape, regardless of the cross-sectional shape of this portion. Thus, this term designates both circular and substantially circular cross-section clongate material portions, and beam or bar-shaped material portions including for example a cylindrical in shape or substantially rectangular cross-section.

The epitaxial layers 208 in channel region(s) may eventually be removed and serve to define a vertical distance between adjacent channel members for a to-be-formed multi-gate devices and the thickness is chosen based on device performance considerations. Accordingly, the epitaxial layers 208 may also be referred to as sacrificial layers, and the epitaxial layers 206 may also be referred to as channel layers.

It is noted that three (3) layers of the epitaxial layers 206 and three (3) layers of the epitaxial layers 208 are alternately arranged as illustrated in FIG. 11, which is for illustrative purposes only and not intended to be limiting beyond what is specifically recited in the claims. It can be appreciated that any number of epitaxial layers can be formed in the epitaxial stack 204; the number of layers depending on the desired number of channels members for the multi-gate devices. In some embodiments, the number of epitaxial layers 206 is between 2 and 10. It is also noted that while the epitaxial layers 206, 208 are shown as having a particular stacking sequence, where an epitaxial layer 206 is the topmost layer of the epitaxial stack 204, other configurations are possible. For example, in some cases, an epitaxial layer 208 may alternatively be the topmost layer of the epitaxial stack 204. Stated another way, the order of growth for the epitaxial layers 206, 208, and thus their stacking sequence, may be switched or otherwise be different than what is shown in the figures, while remaining within the scope of the present disclosure.

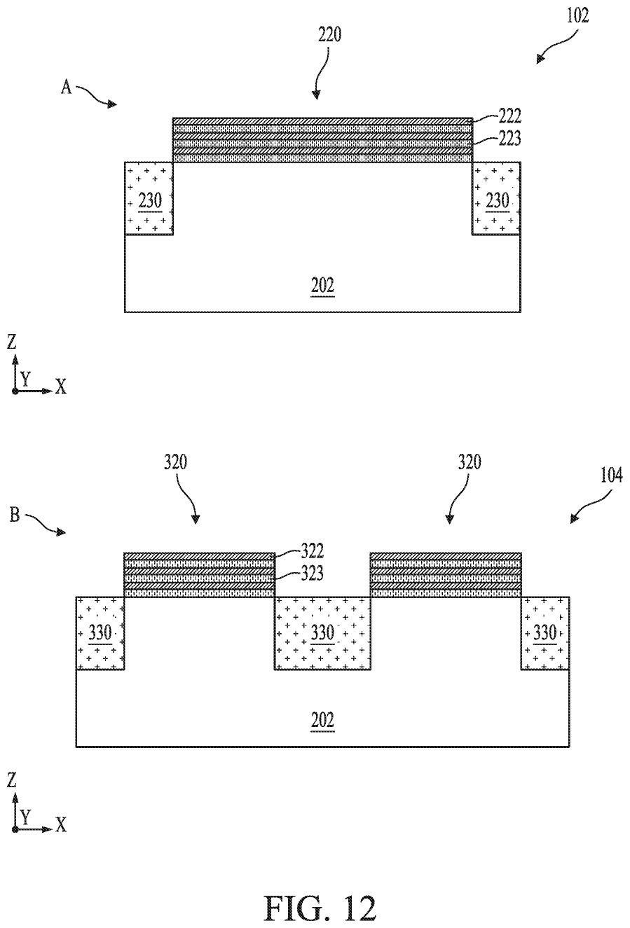

At operation 404, referring to FIGS. 10 and 12, the method 400 patterns the epitaxial stack 204 and a top portion of the substrate 202 to form fin-like active regions, particularly fin-like active regions 220 in the circuit region 102 and fin-like active regions 320 in the seal ring region 104. In various embodiments, each of the fin-like active regions 220, 320 includes a base portion formed from the substrate 202 and an epitaxial stack portion formed from portions of each of the epitaxial layers of the initial epitaxial stack 204 including epitaxial layers 206 and 208. After the patterning, the epitaxial layers 206 in the fin-like active regions 220 are denoted as channel layers (or channel members) 222, the epitaxial layers 206 in the fin-like active regions 320 are denoted as channel layers (or channel members) 322; the epitaxial layers 208 in the fin-like active regions 220 are denoted as sacrificial layers 223, and the epitaxial layers 208 in the fin-like active regions 320 are denoted as sacrificial layers 323. The fin-like active regions 220, 320 may be fabricated using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fin-like active regions 220, 320 by etching initial epitaxial stack 204. The etching process can include dry etching, wet etching, reactive ion etching (RIE), and/or other suitable processes.

The method 400 at the operation 404 also forms the isolation structures 230, 330, such as shallow trench isolation (STI) features, between the fin-like active regions 220, 320, respectively. Still referring to FIG. 12, the STI features are portions of one STI layer disposed on the substrate 202 interposing the fin-like active regions 220, 320. The portions of the STI layer surrounding the fin-like active regions 220 in the circuit region 102 are denoted as STI features 230, and the portions of the STI layer surrounding the fin-like active regions 320 in the seal ring region 104 are denoted as STI features 330. By way of example, in some embodiments, a dielectric layer is first deposited over the substrate 202, filling the trenches between fin-like active regions with dielectric material. In some embodiments, the dielectric layer may include silicon oxide, silicon nitride, silicon oxynitride, fluorine-doped silicate glass (FSG), a low-k dielectric, combinations thereof, and/or other suitable materials. In various examples, the dielectric layer may be deposited by a CVD process, a SACVD process, a flowable CVD process, an ALD process, a PVD process, and/or other suitable process. In some embodiments, after deposition of the dielectric layer, the semiconductor structure 100 may be annealed, for example, to improve the quality of the dielectric layer. In some embodiments, the dielectric layer may include a multi-layer structure, for example, having one or more liner layers. After deposition of the dielectric layer, the deposited dielectric material is thinned and planarized, for example by a chemical mechanical polishing (CMP) process. Subsequently, the dielectric layer interposing the fin-like active regions 220, 320 are recessed. In some embodiments, the recessing process may include a dry etching process, a wet etching process, and/or a combination thereof. In some embodiments, a recessing depth is controlled (e.g., by controlling an etching time) so as to expose each layer of the initial epitaxial stack 204.

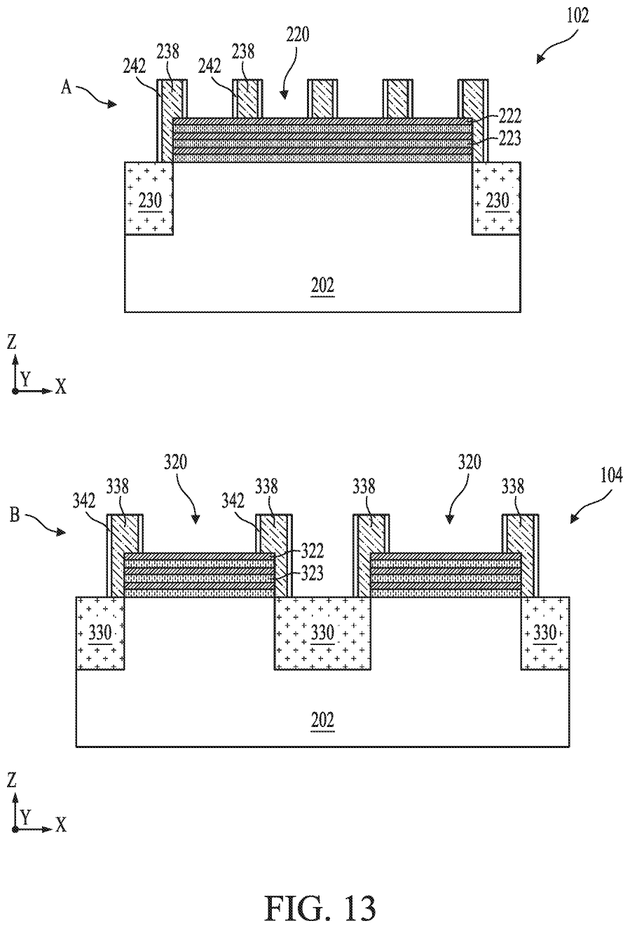

At operation 406, referring to FIGS. 10 and 13, the method 400 forms dummy gate structures 238, 338 over the active regions 220, 320, respectively. While the present discussion is directed to a replacement gate (or gate-last) process whereby a dummy gate structure (or referred to as a sacrificial gate structure) is formed and subsequently replaced, other configurations may be possible. The dummy gate structures 238, 338 will be replaced by metal gate structures at a subsequent processing stage of the method 400. The dummy gate structures 238, 338 may also define source/drain regions of the respective active regions, for example, the portions of the active regions between adjacent dummy gate structures. In the circuit region 102, the dummy gate structures 238 are deposited over center portions and two end portions of the active region 220. In the seal ring region 104, the dummy gate structures 338 are deposited over edge portions of the active regions 320 and the STI features 330.

In some embodiments, the dummy gate structures 238, 338 are formed by various process steps such as layer deposition, patterning, etching, as well as other suitable processing steps. Exemplary layer deposition processes include CVD (including low-pressure CVD, plasma-enhanced CVD, and/or flowable CVD), PVD, ALD, thermal oxidation, e-beam evaporation, or other suitable deposition techniques, or combinations thereof. In some embodiments, the dummy gate structures include a dummy dielectric layer and a dummy electrode layer. In some embodiments, the dummy dielectric layer may include SiO₂, silicon nitride, a high-k dielectric material and/or other suitable material. Subsequently, the dummy electrode layer is deposited. In some embodiments, the dummy electrode layer may include polycrystalline silicon (polysilicon). In forming the dummy gate structures for example, the patterning process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. In some embodiments, the dummy gate structures are patterned through a patterned hard mask.

Still referring to FIG. 13, the method 400 at the operation 406 also forms gate spacers 242 on sidewall surfaces of the dummy gate structures 238 and gate spacers 342 on sidewall surfaces of the dummy gate structures 338. In some embodiments, after the dummy gate structures 238, 338 are formed, a blanket layer of an insulating material for sidewall spacers is conformally formed by using CVD or other suitable methods. The blanket layer is deposited in a conformal manner so that it is formed to have substantially equal thicknesses on various surfaces, such as the sidewalls, horizontal surfaces, and the top of the dummy gate structures. In some embodiments, the blanket layer is deposited to a thickness in a range from about 2 nm to about 10 nm. In one embodiment, the insulating material of the blanket layer is a silicon nitride-based material, such as SiN, SiON, SiOCN or SiCN and combinations thereof. The blanket layer is then etched using an anisotropic process to form gate spacers 242 on opposite sidewalls of the dummy gate structures 238 and gate spacers 342 on opposite sidewalls of the dummy gate structures 338. The anisotropic etching performed on the blanket layer can be, for example, reactive ion etching (RIE). During the anisotropic etching process, most of the insulating material is removed from horizontal surfaces, leaving the dielectric spacer layer on the vertical sidewall surfaces of the dummy gate structures 238, 338 as the gate spacers 242, 342, respectively.

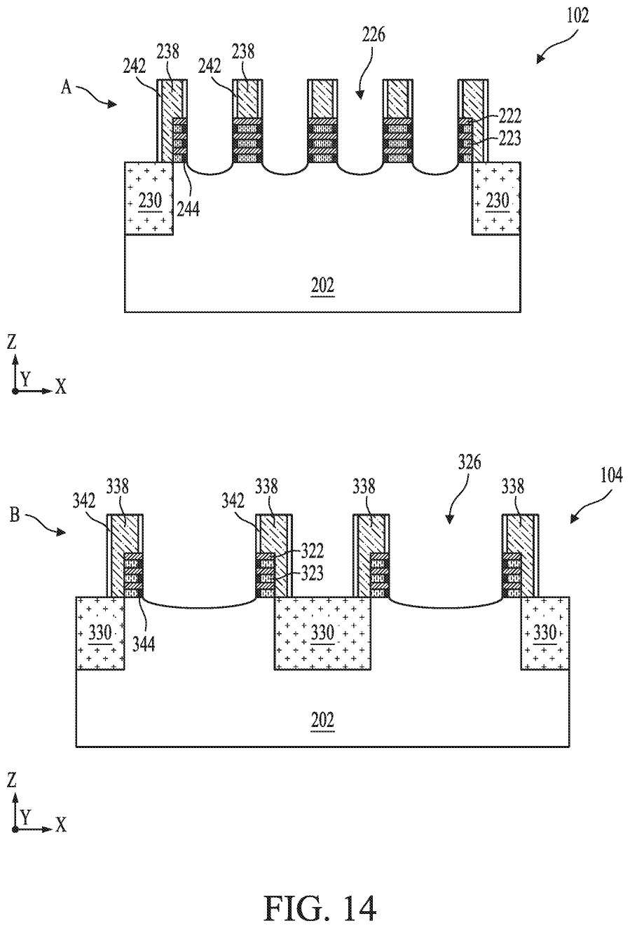

At operation 408, referring to FIGS. 10 and 14, the method 400 recesses the S/D regions in the active regions 220, 320 in forming S/D recesses 226, 326, respectively. In some embodiments, a source/drain etch process is performed to form the S/D recesses 226, 326 by removing portions of the active regions 220, 320 not covered by the dummy gate structures 238, 338 (e.g., in source/drain regions) and that were previously exposed. In particular, the source/drain etch process may serve to remove the exposed epitaxial layer portions 222, 223 and 322, 323 in source/drain regions of the semiconductor structure 100 to expose the top portion of the substrate 202. In some embodiments, the source/drain etch process may include a dry etching process, a wet etching process, and/or a combination thereof. In some embodiments, a recessed depth is controlled (e.g., by controlling an etching time) such that the top portion of the substrate 202 is recessed to be under the top surface of the STI features 230, 330.

Still referring to FIG. 14, the method 400 at the operation 408 also forms inner spacers. In some embodiments, inner spacer cavities are formed by laterally recessing the epitaxial layers 223 through S/D recesses 226 and the epitaxial layers 323 through S/D recesses 326, and inner spacers are subsequently formed in the inner spacer cavities. The portions of the inner spacers in the circuit region 102 is denoted as inner spacers 244, and the portions of the inner spacers in the seal ring region 104 is denoted as inner spacers 344. In the circuit region 102, the inner spacers 244 are disposed on both ends of the epitaxial layer 223; in the seal ring region 104, the inner spacers 344 are disposed on one end of the epitaxial layer 323, as the other end of the epitaxial layer 323 is covered by the dummy gate structure 338. In some embodiments, a lateral etching (or horizontal recessing) is performed to recess the epitaxial layers 223, 323 to form inner spacer cavities. The amount of etching of the epitaxial layers 223, 323 is in a range from about 2 nm to about 10 nm in some embodiments. When the epitaxial layers 223, 323 are SiGe, the lateral etching process may use an etchant selected from, but not limited to, ammonium hydroxide (NH4OH), tetramethylammonium hydroxide (TMAH), ethylenediamine pyrocatechol (EDP), and potassium hydroxide (KOH) solutions. Subsequently, an insulating layer is formed on the lateral ends of the epitaxial layers 223, 323 to fill the inner spacer cavities, thereby forming inner spacers 244, 344, respectively. The insulating layer may include a dielectric material, such as SiN, SiOC, SiOCN, SiCN, SiO₂, and/or other suitable material. In some embodiments, the insulating layer is conformally deposited in the S/D recesses 226, 326, for example, by ALD or any other suitable method. After the conformal deposition of the insulating layer, an etch-back process is performed to partially remove the insulating layer from outside of the inner spacer cavities. By this etching the insulating layer remains substantially within the inner spacer cavities.

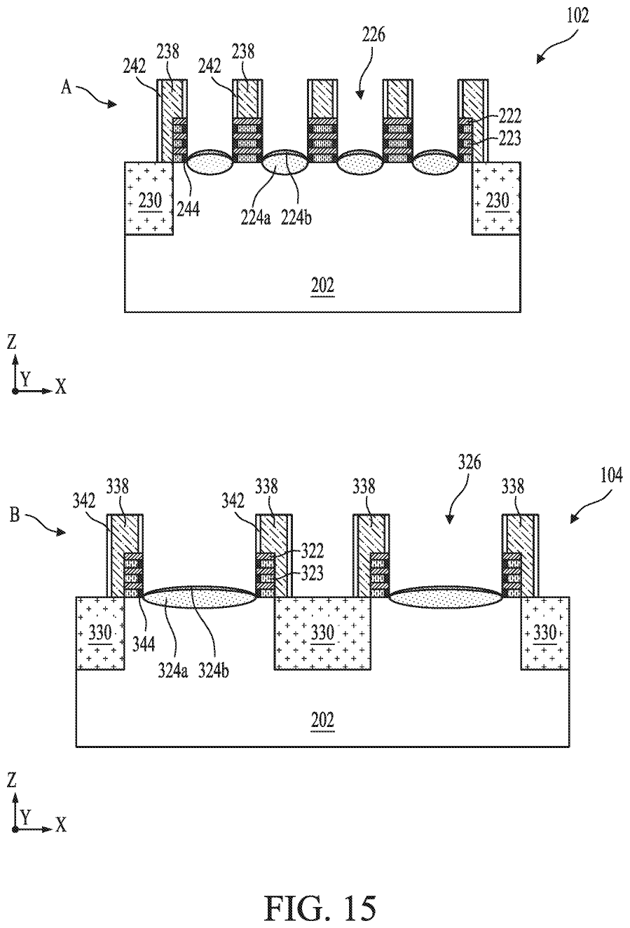

At operation 410, referring to FIGS. 10 and 15, the method 400 forms a buffer epitaxial layer 224a at the bottom of the S/D recesses 226 in the circuit region 102 and a buffer epitaxial layer 324a at the bottom of the S/D recesses 326 in the scal ring region 104. The buffer epitaxial layers 224a, 324a are epitaxially grown from the recessed top portion of the substrate 202 in the S/D regions. The buffer epitaxial layers 224a, 324a may also be referred to as the lower epitaxial layers. By way of example, epitaxial growth of the buffer epitaxial layers 224a, 324a may be performed by vapor-phase epitaxy (VPE), ultra-high vacuum CVD (UHV-CVD), molecular beam epitaxy (MBE), and/or other suitable processes. In some embodiments, the buffer epitaxial layers 224a, 324a include the same material as the substrate 202, such as silicon (Si). In some alternative embodiments, the buffer epitaxial layers 224a, 324a include a different semiconductor material than the Si substrate 202, such as SiGe, SiSn, or other suitable semiconductor material. In some embodiments, the buffer epitaxial layers 224a, 324a are dopant-free, where for example, no intentional doping is performed during the epitaxial growth process. As a comparison, in one instance, the substrate 202 is lightly doped and has a higher doping concentration than the buffer epitaxial layers 224a, 324a. The buffer epitaxial layers 224a, 324a provides a high resistance path from the S/D regions to the semiconductor substrate, such that the leakage current in the semiconductor substrate is suppressed. The method 400 at the operation 410 may optionally deposit an insulating film, such as a nitride film, over the buffer epitaxial layers 224a, 324a to further block the leakage current path. The portions of the insulating film covering the buffer epitaxial layer 224a in the circuit region 102 is denoted as insulating film 224b, and the portions of the insulating film covering the buffer epitaxial layer 324a in the seal ring region 104 is denoted as insulating film 324b. The insulating films 224b, 324b may be deposited by ALD or any other suitable method. In the seal ring region 104, compared with depositing the dummy gate structures 338 in a center portion of the active regions 320, depositing the dummy gate structures 338 on edge portions of the active regions 320 as in the present embodiment spares a larger opening for the S/D recesses 326, which facilitates the deposition of the insulating film 324b.

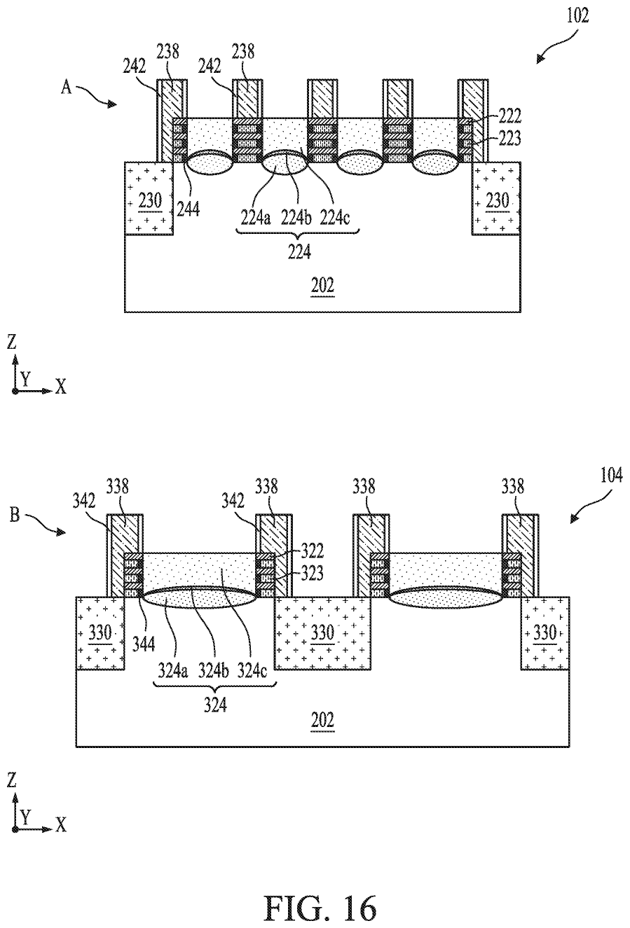

At operation 412, referring to FIGS. 10 and 16, the method 400 forms upper epitaxial layer 224c over the buffer epitaxial layer 224a and upper epitaxial layer 324c over the buffer epitaxial layer 324a. The buffer epitaxial layer 224a and the upper epitaxial layer 224c (and optionally the insulating film 224b) collectively define source/drain features 224 in the circuit region 102. The buffer epitaxial layer 324a and the upper epitaxial layer 324c (and optionally the insulating film 324b) collectively define source/drain features 324 in the seal ring region 104. By way of example, epitaxial growth of the upper epitaxial layers 224c, 324c may be performed by vapor-phase epitaxy (VPE), ultra-high vacuum CVD (UHV-CVD), molecular beam epitaxy (MBE), and/or other suitable processes. The upper epitaxial layers 224c, 324c may include Si, SiP, SiAs, SiC, SiGe, SiSn, or other suitable semiconductor material. The upper epitaxial layer 256 may be doped with dopants such as arsenic (As), phosphorus (P), germanium (Ge) or boron (B). Generally, the upper epitaxial layers 224c, 324c includes higher dopant concentration than the buffer epitaxial layers 224a, 324a. In some embodiments, the upper epitaxial layers 224c, 324c includes the same semiconductor material with the buffer epitaxial layers 224a, 324a but with a higher dopant concentration. In some embodiments, the upper epitaxial layers 224c, 324c includes different semiconductor material from the buffer epitaxial layers 224a, 324a and with a higher dopant concentration. The upper epitaxial layers 224c, 324c may have the same crystalline orientation with the substrate 202 and the buffer epitaxial layers 224a, 324a.

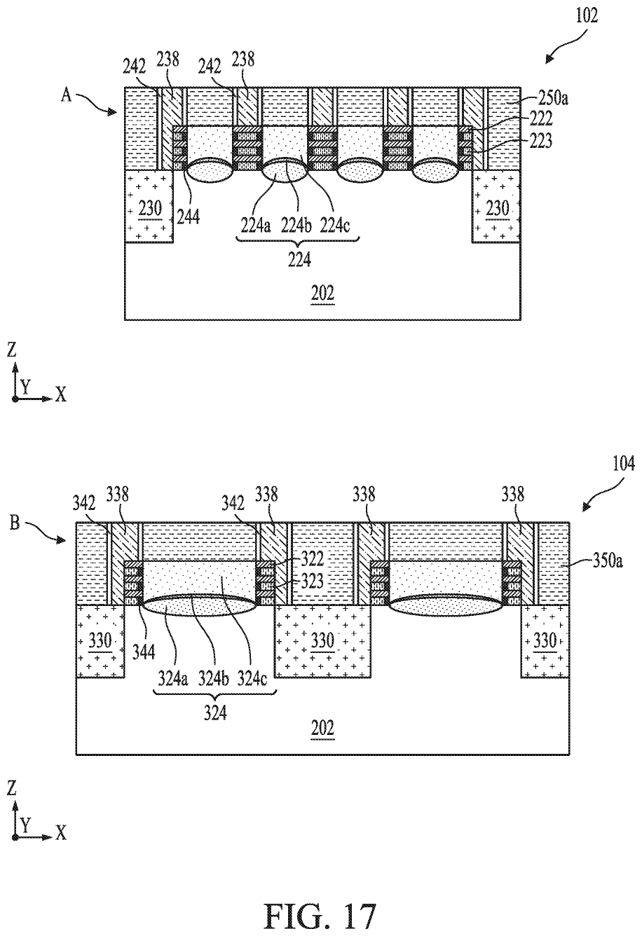

At operation 414, referring to FIGS. 10 and 17, the method 400 forms lower interlayer dielectric (ILD) layer over the source/drain features 224, 324, the gate spacers 242, the dummy gate structures 238, 338, and the isolation structures 230. A contact etch stop layer (CESL) (not shown) may be deposited as a blanket layer prior to the formation of the lower ILD layer, and the lower ILD layer is deposited over the CESL. The portion of the lower ILD layer in the circuit region 102 is denoted as lower ILD layer 250a, and the portion of the lower ILD layer in the seal ring region 104 is denoted as lower ILD layer 350a. In some embodiments, the CESL includes a silicon nitride layer, silicon oxide layer, a silicon oxynitride layer, and/or other materials known in the art. The CESL may be formed by plasma-enhanced chemical vapor deposition (PECVD) process and/or other suitable deposition or oxidation processes. In some embodiments, the lower ILD layer includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The lower ILD layer may be deposited by a PECVD process or other suitable deposition technique. In some embodiments, after formation of the lower ILD layer, the semiconductor structure 100 may be subject to a high thermal budget process to anneal the lower ILD layer. After depositing the lower ILD layer, a planarization process may be performed to remove excessive dielectric materials. For example, a planarization process includes a chemical mechanical planarization (CMP) process which removes portions of the lower ILD layer (and the CESL, if present) overlying the dummy gate structures 238, 338 and planarizes a top surface of the semiconductor structure 100.

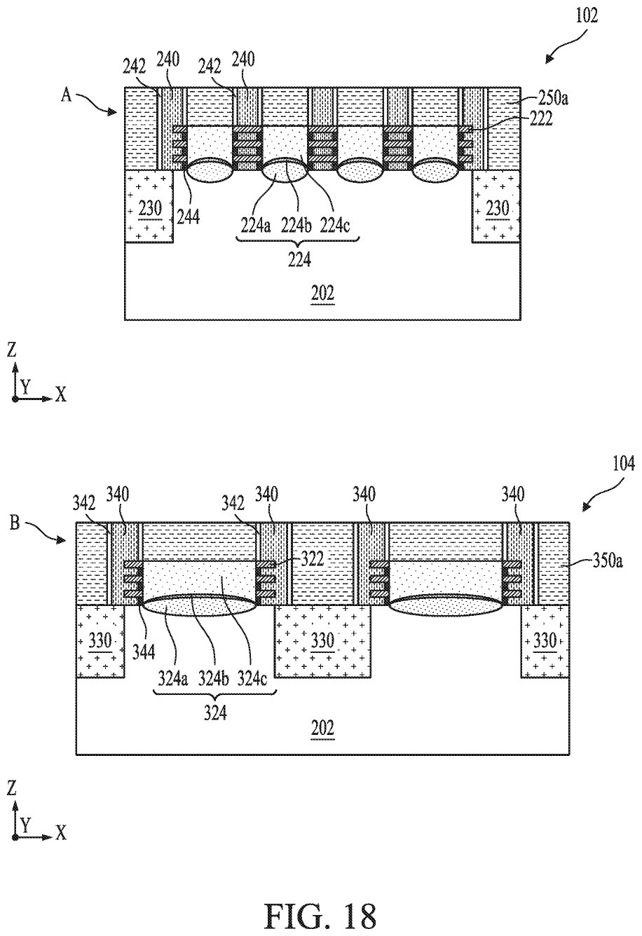

At operation 416, referring to FIGS. 10 and 18, the method 400 replaces the dummy gate structures 238, 338 with a metal gate structures 240, 340, respectively. In some embodiments, the operation 416 may include one or more etching processes that remove the dummy gate structures 238, 338 in forming gate trenches. For example, the removal of the dummy gate structures 238, 338 may be performed using a selective etch process such as a selective wet etch, a selective dry etch, or a combination thereof. The operation 416 also removes the epitaxial layers (sacrificial layers) 223, 323 from the gate trenches. In an embodiment, the sacrificial layers 223, 323 include SiGe and the epitaxial layers (channel layers, or channel members) 222, 322 are silicon, allowing for the selective removal of the sacrificial layers 223, 323. In an embodiment, the sacrificial layers 223, 323 are removed by a selective wet etching process. In some embodiments, the selective wet etching includes an APM etch (e.g., ammonia hydroxide-hydrogen peroxide-water mixture). In some embodiments, the selective removal includes SiGe oxidation followed by a SiGeOₓ removal. For example, the oxidation may be provided by O₃ clean and then SiGeOₓ removed by an etchant such as NH4OH. Subsequently, the operation 416 forms metal gate structures 240, 340 in the gate trenches.

In some embodiments, each of the metal gate structures 240, 340 includes an interfacial layer (not shown), a high-K gate dielectric layer formed over the interfacial layer, and a gate electrode layer formed over the high-k gate dielectric layer. High-k gate dielectrics, as used and described herein, include dielectric materials having a high dielectric constant, for example, greater than that of thermal silicon oxide (˜3.9). The gate electrode layer may include a metal, metal alloy, or metal silicide. Additionally, the formation of the metal gate structures 240, 340 may include depositions to form various gate materials, one or more liner layers, and one or more planarization processes, such as CMP processes, to remove excessive gate materials and thereby planarize a top surface of the semiconductor structure 100. As discussed above, the active region widths with a ratio between about 1.1 and about 5, the active region aerial densities with a difference within about 10%, similar metal gate structure widths, the metal gate structure aerial densities with a difference within about 10%, and other measures implemented, improve the uniformity of the elements in the circuit region and scal ring region, which mitigates dishing effect during the planarization processes.

The metal gate structures 240 include portions that interpose and wrap around middle portions of each of the epitaxial layers 222, which form channels of the functional multi-gate devices in the circuit region 102. The two end portions of each of the epitaxial layers 222 are in contact with two opposing source/drain features 224. The metal gate structures 340 includes portions that interpose and partially wrap around end portions on one side of the epitaxial layers 322. End portions on an opposing side of the epitaxial layers 322 are in contact with a source/drain feature 324. In some embodiments, the interfacial layer of the metal gate structures 240, 340 may include a dielectric material such as silicon oxide (SiO₂), HfSiO, or silicon oxynitride (SiON). The interfacial layer may be formed by chemical oxidation, thermal oxidation, atomic layer deposition (ALD), chemical vapor deposition (CVD), and/or other suitable method. The high-k gate dielectric layer of the metal gate structures 240, 340 may include a high-K dielectric such as hafnium oxide (HfO₂). Alternatively, the high-k gate dielectric layer may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material. The high-k gate dielectric layer may be formed by ALD, physical vapor deposition (PVD), CVD, oxidation, and/or other suitable methods. The gate electrode layer may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include Ti, Ag, Al, TiAlN, TaC, TaCN, TaSiN, Mn, Zr, TiN, TaN, Ru, Mo, Al, WN, Cu, W, Re, Ir, Co, Ni, other suitable metal materials or a combination thereof. In various embodiments, the gate electrode layer may be formed by ALD, PVD, CVD, e-beam evaporation, or other suitable process. Further, the gate electrode layer may be formed separately for NFET and PFET transistors in the circuit region 102 which may use different metal layers (e.g., for providing an n-type or p-type work function), while the gate electrode layer in the seal ring region 104 may be formed simultaneously and thus have the same composition with one of the NFET or PFET transistors in the circuit region 102.

At operation 418, referring to FIGS. 10 and 19, the method 400 forms contact structures, vias, and overlying interconnect structures. In some embodiments, the operation 418 includes depositing an upper ILD layers 250b, 350b over the lower ILD layers 250a, 350a, respectively; forming source/drain contacts 260, 360 through the upper and lower ILD layers and landing on the source/drain features 224, 324, respectively; depositing etch stop layer 270, 370 and dielectric layer 272, 372 over the upper ILD layers 250b, 350b, respectively; forming gate contacts 284 through the dielectric layer 272, the etch stop layer 270, and the upper ILD layer 250b and landing on the gate structure 240; forming source/drain contact vias 282, 382 through the dielectric layer 272, the etch stop layer 270 and landing on the source/drain contacts 260, 360, respectively; and forming an interconnect structure including a plurality of insulating layers 274, 374 (also referred to as intermetal dielectric (IMD) layers) and conductive features, such as metal lines 286, 386 and vias 288, 388, in the insulating layers 274, 374, respectively. The insulating layers 274, 374 may be formed from an extra-low-k (ELK) dielectric material having a k-value of less than 2.5. The interconnect structures may further include etch stop layers (not shown) stacked between adjacent insulating layers.

In the seal ring region 104, the seal ring structure vertically extends from the substrate, through the interconnect structure, and up to the passivation layer (not shown) in the semiconductor structure 100. Further, in the illustrated embodiment of FIG. 19, the seal ring structure extends to the interconnect structure through the source/drain contacts 360 and the source/drain contact vias 382, while the gate structures 340 in the seal ring region 104 are free of gate contacts landing thereon. Still further, due to the spacing between adjacent seal ring structures, not all the source/drain features 324 are connected to the interconnect structure in order to spare space for the conductive features above adjacent source/drain features 324 to have sufficient width.

Regarding the alternative embodiment discussed above in association with FIGS. 8A and 8B. FIG. 20 illustrates the cross-sectional views of the alternative embodiment after the formation of the interconnect structure with the dummy gate structure 340d disposed between gate structures 340. The dummy gate structures 340d may be free of gate contacts landing thereon.

Regarding the alternative embodiment discussed above in association with FIGS. 9A and 9B, FIG. 21 illustrates the cross-sectional views of the alternative embodiment after the formation of the interconnect structure with the dummy contact structure 360d disposed between gate structures 340 and covered under the etch stop layer 370. Further, the seal ring structure may extend to the interconnect structure through the gate contacts 384 but not through the source/drain contact structures 360. In the illustrated embodiment, the metal line 386 connects gate contacts 384 extending from two adjacent gate structures 340, while the source/drain feature 324 in the seal ring region 104 may even be free of the contact structures 360 landing thereon to spare space for the interconnect structure formed above.

The present disclosure provides the seal ring structure with active regions, gate structures, and contact structures configured with effect protection to the devices in the circuit region. The active regions, gate structures, and contact structures in the seal ring region are designed and configured to maintain uniformity from counterpart clements in the circuit regions in terms of dimensions, pitches, orientations and other parameters.

In one example aspect, the present disclosure is directed to a semiconductor structure. The semiconductor structure includes a substrate having a circuit region and a seal ring region around the circuit region, first active regions of a first width disposed in the circuit region, second active regions of a second width disposed in the seal ring region, the second width being greater than the first width, first gate structures disposed on the first active regions, the first gate structures being longitudinally oriented to be orthogonal with the first active regions, and second gate structures disposed on longitudinal edges of the second active regions, the second gate structures being longitudinally oriented to be in parallel with the second active regions. In some embodiments, a ratio of the second width over the first width ranges between 1.1 and 5. In some embodiments, the first gate structures have a third width, and the second gate structures have a fourth width that is substantially equal to the third width. In some embodiments, each of the second gate structures overlaps with a respective one of the second active regions for a width between 5 nm and 15 nm measured from a respective one of the longitudinal edges towards a centerline of the respective one of the second active regions. In some embodiments, the first active regions occupy a first percentile of a first area in the circuit region, the second active regions occupy a second percentile of a second area in the seal ring region, and a difference between the first percentile and the second percentile is within 10%. In some embodiments, the first gate structures occupy a first percentile of a first area in the circuit region, the second gate structures occupy a second percentile of a second area in the seal ring region, and a difference between the first percentile and the second percentile is within 10%. In some embodiments, the semiconductor structure further includes contact structures disposed on the second active regions and completely landing on the second active regions. In some embodiments, the contact structures are landing on the second active regions with margins such that longitudinal edges of each of the contact structures are within the longitudinal edges of a respective one of the second active regions. In some embodiments, each of the second active regions is a continuous ring shape to enclose the circuit region, and each of the second gate structures is a continuous ring shape to enclose the circuit region. In some embodiments, the semiconductor structure further includes segmented third active regions disposed in corner areas of the seal ring region, and third gate structures disposed on edges of the third active regions, each of the third gate structures fully surrounding a respective one of the third active regions.

In another example aspect, the present disclosure is directed to a semiconductor structure. The semiconductor structure includes an active region extending lengthwise in a first direction in a region of the semiconductor structure, a first gate structure disposed on a first edge of the active region, the first gate structure extending lengthwise in the first direction in the region of the semiconductor structure, a second gate structure disposed on a second edge of the active region, the second edge opposing the first edge, the second gate structure extending lengthwise in the first direction in the region of the semiconductor structure, and a contact structure completely landing on the active region, the contact structure extending lengthwise in the first direction in the region of the semiconductor structure. In some embodiments, each of the active region, the first gate structure, the second gate structure, and the contact structure is a ring shape. In some embodiments, the ring shape of the contact structure fully surrounds the ring shape of the first gate structure, and the ring shape of the second gate structure fully surrounds the ring shape of the contact structure. In some embodiments, the region is an edge region of the semiconductor structure, the active region extends lengthwise in a second direction in a corner region of the semiconductor structure, and the second direction is about 45 degrees tilted with respect to the first direction. In some embodiments, the active region includes multiple channel members vertically stacked. In some embodiments, the semiconductor structure further includes an isolation feature surrounding the active region, and a third gate structure disposed completely on the isolation feature, the third gate structure extending lengthwise in the first direction in the region of the semiconductor structure, the first and third gate structures sandwiching the second gate structure. In some embodiments, the contact structure is a first contact structure, and the semiconductor structure further includes an isolation feature surrounding the active region, and a second contact structure disposed completely on the isolation feature, the second contact structure extending lengthwise in the first direction in the region of the semiconductor structure, the first and second contact structures sandwiching the second gate structure.

In yet another example aspect, the present disclosure is directed to a method. The method includes forming an epitaxial stack over a substrate, the epitaxial stack including first and second epitaxial layers of different material compositions and alternatively stacked in a vertical direction to the substrate, patterning the epitaxial stack to form a fin, depositing a first dummy gate structure on a first longitudinal edge of the fin and a second dummy gate structure on a second longitudinal edge of the fin, each of the first and second dummy gate structures extending longitudinally in parallel with the fin, etching a portion of the fin between the first and second dummy gate structures to form a recess, forming an epitaxial feature in the recess, removing the first and second dummy gate structures to form first and second gate trenches, respectively, removing the second epitaxial layers from the first and second gate trenches, and depositing a first metal gate structure in the first gate trench and a second metal gate structure in the second gate trench. In some embodiments, the method further includes forming a contact structure landing on the epitaxial feature, the contact structure being completely confined within the first and second longitudinal edges of the fin. In some embodiments, the first metal gate structure has a first ring shape, and the second metal gate structure has a second ring shape that is substantially concentric with the first ring shape.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate having a circuit region and a seal ring region around the circuit region;
first active regions of a first width disposed in the circuit region;
second active regions of a second width disposed in the seal ring region, wherein the second width is greater than the first width;
first gate structures disposed on the first active regions, wherein the first gate structures are longitudinally oriented to be orthogonal with the first active regions; and
second gate structures disposed on longitudinal edges of the second active regions, wherein the second gate structures are longitudinally oriented to be in parallel with the second active regions.

2. The semiconductor structure of claim 1, wherein a ratio of the second width over the first width ranges between 1.1 and 5.

3. The semiconductor structure of claim 1, wherein the first gate structures have a third width, and the second gate structures have a fourth width that is substantially equal to the third width.

4. The semiconductor structure of claim 1, wherein each of the second gate structures overlaps with a respective one of the second active regions for a width between 5 nm and 15 nm measured from a respective one of the longitudinal edges towards a centerline of the respective one of the second active regions.

5. The semiconductor structure of claim 1, wherein the first active regions occupy a first percentile of a first area in the circuit region, the second active regions occupy a second percentile of a second area in the seal ring region, and a difference between the first percentile and the second percentile is within 10%.

6. The semiconductor structure of claim 1, wherein the first gate structures occupy a first percentile of a first area in the circuit region, the second gate structures occupy a second percentile of a second area in the seal ring region, and a difference between the first percentile and the second percentile is within 10%.

7. The semiconductor structure of claim 1, further comprising:
contact structures disposed on the second active regions and completely landing on the second active regions.

8. The semiconductor structure of claim 7, wherein the contact structures are landing on the second active regions with margins such that longitudinal edges of each of the contact structures are within the longitudinal edges of a respective one of the second active regions.

9. The semiconductor structure of claim 1, wherein each of the second active regions is a continuous ring shape to enclose the circuit region, and each of the second gate structures is a continuous ring shape to enclose the circuit region.

10. The semiconductor structure of claim 9, further comprising:
third active regions disposed in corner areas of the seal ring region, wherein the third active regions are segmented; and
third gate structures disposed on edges of the third active regions, wherein each of the third gate structures fully surrounds a respective one of the third active regions.

11. A semiconductor structure, comprising:
an active region extending lengthwise in a first direction in a region of the semiconductor structure;
a first gate structure disposed on a first edge of the active region, the first gate structure extending lengthwise in the first direction in the region of the semiconductor structure;
a second gate structure disposed on a second edge of the active region, the second edge opposing the first edge, the second gate structure extending lengthwise in the first direction in the region of the semiconductor structure; and
a contact structure completely landing on the active region, the contact structure extending lengthwise in the first direction in the region of the semiconductor structure.

12. The semiconductor structure of claim 11, wherein each of the active region, the first gate structure, the second gate structure, and the contact structure is a ring shape.

13. The semiconductor structure of claim 12, wherein the ring shape of the contact structure fully surrounds the ring shape of the first gate structure, and the ring shape of the second gate structure fully surrounds the ring shape of the contact structure.

14. The semiconductor structure of claim 11, wherein the region is an edge region of the semiconductor structure, the active region extends lengthwise in a second direction in a corner region of the semiconductor structure, and the second direction is about 45 degrees tilted with respect to the first direction.

15. The semiconductor structure of claim 11, wherein the active region includes multiple channel members vertically stacked.

16. The semiconductor structure of claim 11, further comprising:
an isolation feature surrounding the active region; and
a third gate structure disposed completely on the isolation feature, the third gate structure extending lengthwise in the first direction in the region of the semiconductor structure, the first and third gate structures sandwiching the second gate structure.

17. The semiconductor structure of claim 11, wherein the contact structure is a first contact structure, the semiconductor structure further comprising:
an isolation feature surrounding the active region; and
a second contact structure disposed completely on the isolation feature, the second contact structure extending lengthwise in the first direction in the region of the semiconductor structure, the first and second contact structures sandwiching the second gate structure.

18. A method, comprising:
forming an epitaxial stack over a substrate, the epitaxial stack including first and second epitaxial layers of different material compositions and alternatively stacked in a vertical direction to the substrate;
patterning the epitaxial stack to form a fin;
depositing a first dummy gate structure on a first longitudinal edge of the fin and a second dummy gate structure on a second longitudinal edge of the fin, each of the first and second dummy gate structures extending longitudinally in parallel with the fin;
etching a portion of the fin between the first and second dummy gate structures to form a recess;
forming an epitaxial feature in the recess;
removing the first and second dummy gate structures to form first and second gate trenches, respectively;
removing the second epitaxial layers from the first and second gate trenches; and
depositing a first metal gate structure in the first gate trench and a second metal gate structure in the second gate trench.

19. The method of claim 18, further comprising:
forming a contact structure landing on the epitaxial feature, wherein the contact structure is completely confined within the first and second longitudinal edges of the fin.

20. The method of claim 18, wherein the first metal gate structure has a first ring shape, and the second metal gate structure has a second ring shape that is substantially concentric with the first ring shape.
